(19) United States
(12) Patent Application Publication
(10) Pub. No.: US 2023/0142881 A1
(43) Pub. Date: May 11, 2023

(54) Piezoelectric Micromachined Ultrasonic Transducer

(71) Applicant: Northeastern University, Boston, MA (US)

(72) Inventors: Matteo RINALDI, Boston, MA (US); Flavius POP, Boston, MA (US); Bernard HERRERA, Cambridge, MA (US)

(21) Appl. No.: 17/986,280

(22) Filed: Nov. 14, 2022

Related U.S. Application Data
(60) Provisional application No. 63/278,182, filed on Nov. 11, 2021.

(51) Int. Cl. B81B 3/00

(52) U.S. Cl. CPC B81B 3/0021; H01L 41/1138; B81B 2201/0271; B81B 2203/0127; B81B 2203/0315; B81B 2203/04; B81B 2207/053

(57) ABSTRACT

Devices for ultrasonic transmission and/or reception having a piezoelectric micromachined ultrasonic transducer (pMUT). The device employs a material such as lithium niobate as a piezoelectric layer in a membrane suspended over a cavity. Two activation electrodes on an upper surface of the membrane can activate one or more flexural modes of mechanical vibration in the membrane, the flexural modes of vibration including a displacement in a cross-sectional plane of the membrane. The device can be used individually or in an array. The device can be configured for use in a liquid medium or in biological tissue. A method of operating an ultrasonic transducer is provided. A method of fabrication of an ultrasonic transducer is provided.

### CROSS REFERENCE TO RELATED APPLICATIONS

This application claims benefit under 35 U.S.C. § 119(e) of U.S. Provisional Application No. 63/278,182, filed on 11 Nov. 2021, entitled “Piezoelectric Micromachined Ultrasonic Transducer”, the disclosure of which is hereby incorporated by reference.

### STATEMENT REGARDING FEDERALLY SPONSORED RESEARCH OR DEVELOPMENT

This invention was made with government support under Grant Nos. 1618731 and 1726512 awarded by the National Science Foundation. The government has certain rights in the invention.

### BACKGROUND

In recent years, piezoelectric micromachined ultrasonic transducers (pMUTs) have been explored for a broad range of applications such as fingerprint sensors, range finding, power transfer, and more recently for underwater and intrabody communication. The most investigated piezoelectric materials for pMUTs are aluminum nitride, lead-zirconate-titanate (PZT), and scandium-doped AlN.

The internet of medical things (IoMT) has been the subject of wide research aimed at creating networks of medical devices that continuously acquire medical data from patients and make it available to both the user and healthcare providers. Wearable devices such as smart watches and wrist bands are examples of commercially available devices that provide a diverse collection of health information (heart rate, exercise, sleep patterns, etc.) and can easily connect to the internet. Implantable medical devices (IMDs) are a second category of IoMT devices that can provide data that is more specific to certain organs and parts of the body given their closer proximity to the site of interest due to implantation. These devices also offer site-specific stimulation capabilities for treatment purposes.

Ultrasonic technology has emerged as a viable candidate for implementing intrabody communication, given the wide variety of implantation depths IMDs require. Ultrasonic waves are mechanical in nature and therefore propagate with lower attenuation in human tissue at the frequencies of interest, around 1 MHz. The first demonstration of intrabody communication utilizing ultrasound technology was performed with bulk piezoelectric transducers based on PZT. Good performance in terms of data-rate and penetration of the acoustic waves into the body was shown. However, PZT transducers contain lead, which makes these devices non-bio-compatible and require extra packaging for implanting as part of an IMB. Moreover, their bulky form factor is a further disadvantage in terms of invasiveness for the patients, which also introduces a high risk of infection and rejection from the body. Thus, recent research has been focused on micromachined electro-mechanical systems (MEMS), such as capacitive micromachined ultrasonic transducers (cMUTs) (see FIG. 1A) and piezoelectric micromachined ultrasonic transducers (pMUTs) (see FIG. 1B).

Capacitive MUTs (cMUTs) generally have a suspended membrane on top of a silicon substrate that is actuated (i.e., put in vibration mode) by an electric field as shown in FIG. 1A. This electric field is generated by applying a high DC bias to the membrane (it helps making the membrane more compliant or softer and reduces the gap to the electrode for increased electrostatic force) and an AC driving voltage signal that sets the membrane into motion at its resonance frequency. When in motion, the membrane displaces the particles in the surrounding medium and generates ultrasonic waves that can propagate in the far field of the device and be used as a carrier for an ultrasonic communication link.

Piezoelectric MUTs (pMUTs) have a membrane that moves at its resonance frequency, generating ultrasonic waves as shown in FIG. 1B. The simplest pMUT structure employs a thin-film piezoelectric membrane, for example, made of aluminum nitride (AlN), that is sandwiched between two electrodes (i.e., top and bottom electrodes). When applying a driving AC voltage signal to the electrodes, the AlN starts expanding and contracting in the lateral dimension due to the inverse piezoelectric effect. Since the membrane is clamped and suspended on top of a cavity, this acts as a boundary condition that forces the membrane to vibrate in the Z-axis during its expansion and contraction in the lateral dimension.

For both devices, the key advantage is their miniaturization capability through standardized semiconductor micro-fabrication processes. The main advantages of pMUTs over cMUTs is that they don't require a DC bias to be actuated, therefore making them more appealing for CMOS integration (less complex design and lower power consumption). On the other hand, the key advantage of the pMUTs over bulk transducers is the biocompatibility of the main piezoelectric material they use, the aluminum nitride (AlN) as opposed to the PZT used in the bulk transducers. This allows for the implantation of pMUTs alongside IMDs without the need for additional packaging. A second advantage is the possibility of integrating the pMUT fabrication directly in CMOS foundries, lowering the final product cost and shortening the time to market. Nonetheless, the AlN has a smaller electro-mechanical coupling coefficient compared to other piezoelectric materials such as PZT, meaning that it generates less output pressure when applying the same AC voltage. Recent work has replaced the AlN with micro-machined PZT, which shows better performance but loses the advantage of biocompatibility. Another option is to dope the AlN with scandium (SLAlN), which allows the increase of the electro-mechanical coupling factor. Preliminary results have shown similar performances to that of PZT while maintaining the biocompatibility of the pMUT.

### SUMMARY

The technology described herein provides embodiments of piezoelectric micromachined ultrasonic transducers (pMUTs) having improved properties relating to, for example, bandwidth and electro-mechanical coupling and that can address challenges in the transmission of data from within a body or other medium to an external environment. Since the desired operation frequency for pMUTs is in the low frequency ultrasound range (<1 MHz to avoid attenuation), a larger communication bandwidth (e.g., for underwater and intrabody applications) and stronger electro-mechanical coupling to increase the output pressure of pMUT devices are beneficial, thus increasing the communication range distance and signal-to-noise ratio. The technology described herein can bridge the communication technology gap between implantable medical devices (IMDs) and the end users of the data, such as patients and doctors.

In some embodiments, the pMUTs described herein utilize piezoelectric materials such as, for example, lithium niobate (LN). LN can be X-cut, Y-cut, or Z-cut. Thin-film X-cut lithium niobate offers high performance in terms of kₜ² and Q for laterally vibrating resonators for RF applications, but it has not been used in pMUTs up to now.

Features of the technology include the following:
1. A device for ultrasonic transmission and/or reception, the device comprising:

a substrate, an electrical input port and an electrical output port supported on the substrate, a cavity formed in the substrate;

a membrane suspended over the cavity, the membrane supported on the substrate along opposed edges of the substrate adjacent the cavity, the membrane comprising a piezoelectric layer having an upper surface facing away from the cavity;

two activation electrodes disposed on the upper surface of the membrane, the activation electrodes comprising an input electrode in electrical communication with the electrical input port and an output electrode in electrical communication with the electrical output port, each of the input electrode and the output electrode disposed over the cavity in the substrate and in a parallel alignment with a corresponding one of the opposed edges of the substrate; and

circuitry in communication with the activation electrodes to apply an input signal to excite a flexural mode of mechanical vibration in the membrane, the flexural mode of vibration including a displacement in a cross-sectional plane of the membrane.
2. The device of feature 1, wherein the piezoelectric layer comprises a material having two or more piezoelectric coefficients excitable by activation from the two activation electrodes to couple an electric field in the membrane to the displacement of the membrane.
3. The device of feature 2, wherein the two or more piezoelectric coefficients include a d₃₁ coefficient and a d₁₁ coefficient.
4. The device of any of features 1-3, wherein the piezoelectric layer comprises lithium niobate (LiNbO₃).
5. The device of any of features 1-4, wherein the lithium niobate is X-cut lithium niobate.
6. The device of any of features 1-4, wherein the lithium niobate is X-cut lithium niobate, Y-cut lithium niobate, or Z-cut lithium niobate.
7. The device of any of features 1-6, wherein the two activation electrodes are operable to activate two or more modes of displacement of the membrane.
8. The device of feature 7, wherein the two or more activated modes of displacement are in different directions.
9. The device of any of features 1-8, wherein the two activation electrodes comprise aluminum, a dual layer of titanium and gold, or a metal or combination of metals that can be fabricated with photolithographic techniques.
10. The device of any of features 1-9, further comprising a bottom electrode disposed on a lower surface of the piezoelectric layer facing toward the cavity, the bottom electrode unconnected to the circuitry.
11. The device of feature 10, wherein the bottom electrode extends continuously over the cavity.
12. The device of any of features 10-11, wherein the bottom electrode comprises platinum, aluminum, or molybdenum or combinations thereof.
13. The device of any of features 1-12, wherein the membrane further comprises a support layer disposed on a lower surface of the piezoelectric layer facing toward the cavity, the support layer comprising a dielectric material, a non-conductive material, or an insulating material.
14. The device of feature 13, wherein the support layer comprises silicon dioxide, silicon nitride, or silicon.
15. The device of any of features 1-14, wherein the substrate comprises silicon, quartz, or sapphire.
16. The device of any of features 1-15, having an operable bandwidth of a transmitted sound pressure level of at least 300 kHz, 350 kHz, 400 kHz, 450 kHz, 500 kHz, 1 MHz, 10 MHz, or 100 MHz.
17. The device of any of features 1-16, having one or more peak resonance frequencies of an output signal in the range from 300 kHz to 1 MHz, or from 400 kHz to 800 kHz, or from 500 kHz to 700 kHz.
18. The device of any of features 1-17, wherein the cavity has a width dimension between the opposed edges of the substrate ranging from 1 μm to 1 mm, or from 30 μm to 500 μm.
19. The device of any of features 1-18, wherein each of the input electrode and the output electrode has a width dimension ranging from 1 μm to 100 μm.
20. The device of any of features 1-19, wherein each of the input electrode and the output electrode has a thickness dimension ranging from 10 nm to 500 nm, or from 20 nm to 200 nm.
21. The device of any of features 1-20, wherein the piezoelectric layer has a thickness dimension ranging from 500 nm to 5 μm.
22. The device of any of features 11-12, wherein the bottom electrode has a thickness dimension ranging from 10 nm to 500 nm, or from 20 nm to 200 nm.
23. The device of any of features 13-15, wherein the support layer has a thickness dimension ranging from 500 nm to 5 μm.
24. The device of any of features 1-23, wherein the flexural mode of vibration includes a peak displacement sensitivity ranging from 50 to 100 nm/V.
25. The device of any of features 1-24 configured for use in a liquid medium or in biological tissue.
26. The device of any of features 1-25 configured for use underwater or implanted in a human or non-human mammalian body.
27. A plurality of devices of any of features 1-27, wherein the plurality of devices are arranged in an array.
28. The plurality of devices of feature 27, wherein the input electrodes of each device are electrically connected in rows, the output electrodes of each device are electrically connected in rows, and the rows of the input electrodes are interdigitated between the rows of the output electrodes.
29. An ultrasonic transducer comprising one or more devices of any of features 1-28.
30. The ultrasonic transducer of feature 29, further comprising communication circuitry including a data encoding modulation scheme for transmitting signals to the one or more devices or a decoding modulation scheme for receiving signals from the one or more devices or both.
31. A method of operating the device of any of features 1-30, comprising applying an alternating voltage to the two activation electrodes to excite the flexural mode of mechanical vibration in the membrane.
32. The method of feature 31, wherein the two activation electrodes activate two or more modes of displacement of the membrane.
33. The method of feature 32, wherein the two or more activated modes of displacement are in different directions.
34. The method of any of features 31-33, wherein the piezoelectric layer comprises a material having two or more piezoelectric coefficients excitable by activation from the two activation electrodes to couple an electric field in the membrane to the displacement of the membrane.
35. The method of feature 34, wherein the two or more piezoelectric coefficients include a d₃₁ coefficient and a d₁₁ coefficient.
36. The method of any of features 31-35, further comprising:

placing the device in a liquid medium or biological tissue; and

transmitting an ultrasonic signal into the medium or tissue from the mechanical vibration of the device.
37. The any of feature 36, further comprising exciting two or more modes of displacement in the membrane, and the liquid medium or the biological tissue comprises a damping medium, whereby several resonance frequencies merge together to increase a bandwidth of a transmitted ultrasonic signal into the liquid medium or the biological tissue.
38. A method of fabricating an ultrasonic transducer comprising:

depositing a support layer on a surface of a piezoelectric layer to form a membrane;

bonding the support layer of the membrane to a substrate;

depositing two activation electrodes to a surface of the membrane opposite the support layer, the two activation electrodes comprising an input electrode and an output electrode; and

forming a cavity in the substrate with the membrane suspended over the cavity and supported along opposed edges of the substrate adjacent the cavity, the support layer facing toward the cavity, and each of the input electrode and output electrode disposed over the cavity and in a parallel alignment with a corresponding one of the opposed edges of the substrate.

### DESCRIPTION OF THE DRAWINGS

FIGS. 1A and 1B illustrate prior art micromachined ultrasonic transducers. FIG. 1A illustrates the working principle of a capacitive micromachined ultrasonic transducers(cMUT) and the main composition layers. FIG. 1B illustrates the working principle of a piezoelectric micromachined ultrasonic transducers (pMUT) and the main composition layers.

FIGS. 2A, 2B, and 2C show schematic illustrations of an embodiment of a lithium niobate (LN) pMUT. FIG. 2A illustrates a cross-sectional view of device layers allowing top electrode actuation of a suspended membrane on top of a cavity. FIG. 2B illustrates a top view of a device design showing electrodes, cavity, and bonding pads. FIG. 2C illustrates an embodiment of a pMUT array with N=15 columns and M=15 rows (225 total elements).

FIG. 3A shows a cross section of LN pMUT imaged with a scanning electron microscope. Distinguishable elements are a top electrode (Al), piezoelectric layer (LN), un-patterned bottom electrode (Pt), structural layer (SiO₂) and unreleased substrate (Si).

FIG. 3B shows an optical image of a fabricated 15×15 LN pMUT array. The array is wirebonded to a printed circuit board (PCB) and coated in a Parylene water resistant coating for ultrasonic testing in a de-ionized water tank (see FIG. 10A).

FIG. 3C shows array directivity based on theoretical ultrasonic wave propagation in the XZ plane from the array (left figure) as well as the cross section in the X plane (right figure) at different distances from the pMUT array (1, 5, 10, and 13 cm).

FIG. 4 shows fabrication process steps for a pMUT of the present technology. Steps 1-3 are performed on an X-cut wafer, and then in step 4 the stack is bonded to a silicon carrier wafer and chemo-mechanically polished and trimmed to the desired thickness. The remaining steps are then performed to deposit and pattern the top electrode and trench a cavity with deep reactive ion etching (DRIE) to release the pMUT.

FIGS. 5A-5D illustrate testing. FIG. 5A shows peak displacement measurement of the LN pMUT device with a Digital Holographic Microscope (DHM) and modes matching in COMSOL Multiphysics. FIG. 5B pub shows Fourier transform of the received signal by the pMUT. This shows a bandwidth of BW_{-6 db}≈401 kHz and center frequency of f_{water}≈630 kHz (this is lower than the one in air due to the damping effect of the water). The low Qwater≈2 indicates that most of the energy is radiated, making the LN pMUT a good ultrasonic transmitter and receiver. This bandwidth is higher than pMUTs based on other piezoelectric material such as AlN and ScAlN-36% as shown in FIGS. 10C, 10D, and 10E. FIG. 5C shows attenuation of electromagnetic (EM) and ultrasonic (US) waves when considering both water and tissue phantom as propagation medium. The implantation range considered is from 0 to 15 cm. In water, the EM waves have 3 dB more attenuation than US waves at 15 cm. However, this different dramatically increases in tissue going up to 50 dB, making the US waves the ideal choice for intrabody communication. FIG. 5D shows theoretical Bit-Error-Rate (BER) vs Signal-to-Noise Ratio (SNR) plot for a Quadrature Phase-Shift Keying (QPSK) communication link, which is a protocol suitable for use in the real image transmission. The plot also presents measured BERs at several implantation distances used in the intrabody setup. Some discrepancies are due to the misalignment of the transducers and implantation distance error, which can lead to lower SPL as shown in FIG. 3C.

FIG. 6 illustrates an intrabody setup. LN pMUT arrays, wire-bonded to Printed Circuit Boards (PCBs) were implanted in a tissue phantom mimicking the human tissue properties. When implanting, the incised holes were filled with ultrasound gel to avoid airgaps that could reduce the intensity of the ultrasonic signal. Furthermore, the communication link was implemented with a transmitting and a receiving Universal Software Radio Peripheral (USRP). The signal of the TX USRP was amplified by an off-the-shelf power amplifier while the RX USRP was conditioned by a charge amplifier custom-made to match the impedance of the LN pMUT array. In this setup, both TX and RX were a LN pMUT array.

FIG. 7 illustrates communication results. The ultrasonic channel was tested for Signal-to-Noise Ratio (SNR) and Bit-Error-Rate (BER) at several implantation depths ranging from 3.5 cm up to 13.5 cm. Furthermore, the BER was directly visualized with the transmitted data, an image of Northeastern University campus, in terms of lost or wrong pixel colors. Measurements were done between two LN pMUT arrays implanted in the tissue phantom showed in FIG. 6.

FIGS. 8A-8C illustrate LN pMUT simulation and air measurements. FIG. 8A shows a COMSOL Multiphysics finite element analysis (FEA) simulation of a LN pMUT. The main graph shows the sound pressure level with a predicted resonance frequency at fₐᵢᵣ=657 kHz. The inset graph on the right shows the displacement over the frequency range tested. The two insets on the left show the meshed geometry with the surrounding medium and the main flexural mode of vibration. FIG. 8B shows DHM measurement of the pMUT membrane displacement and its 3D reconstruction for mode analysis. FIG. 8C shows quality factor extraction from the displacement of the pMUT membrane with the ring-down method.

FIGS. 9A-9D illustrate modes merging in air vs. water/tissue. FIG. 9A shows LN pMUT 3D membrane displacement measurement and peak detection in air. Modes are matched to COMSOL

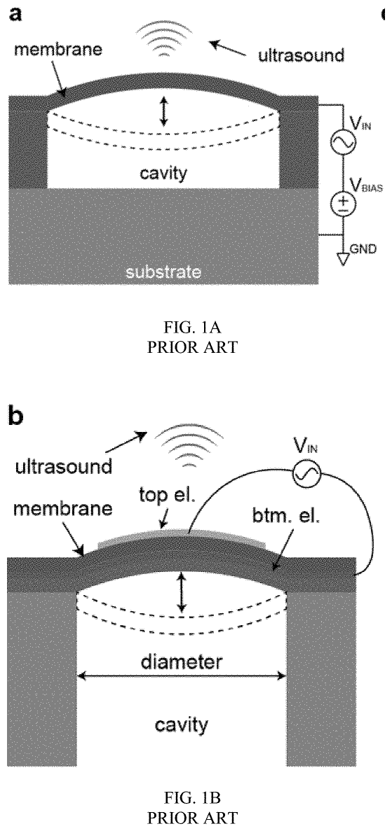

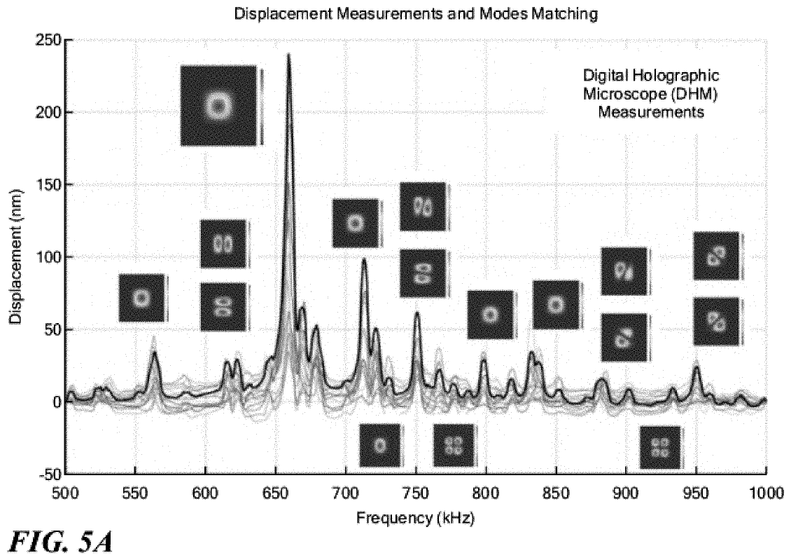

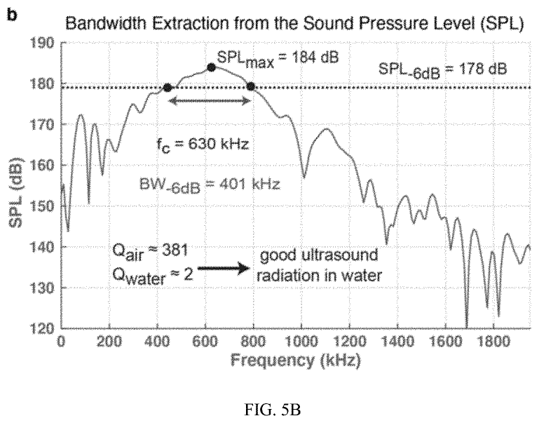

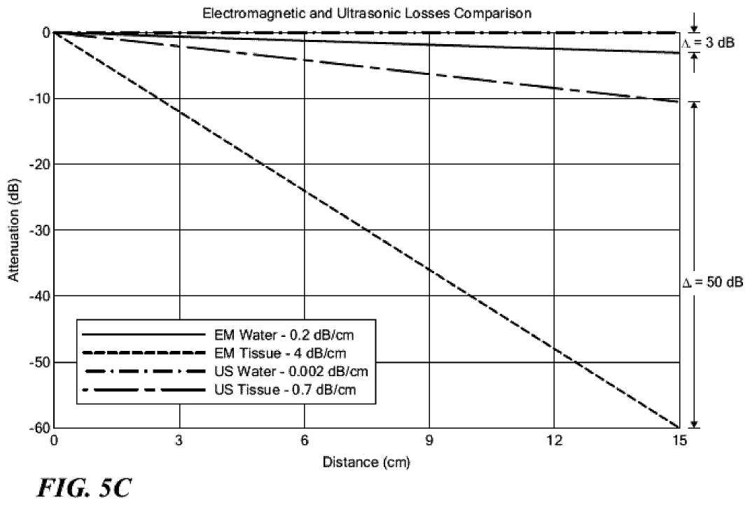

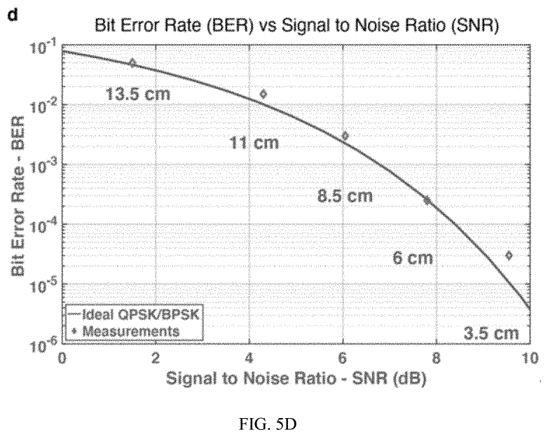

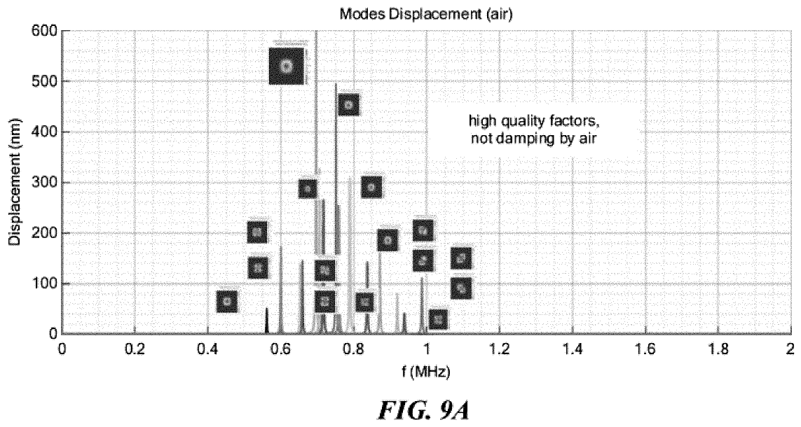

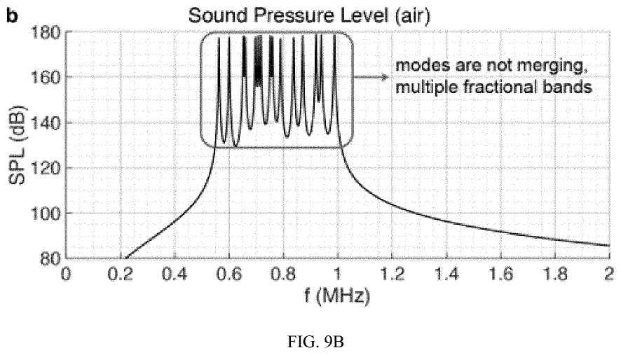

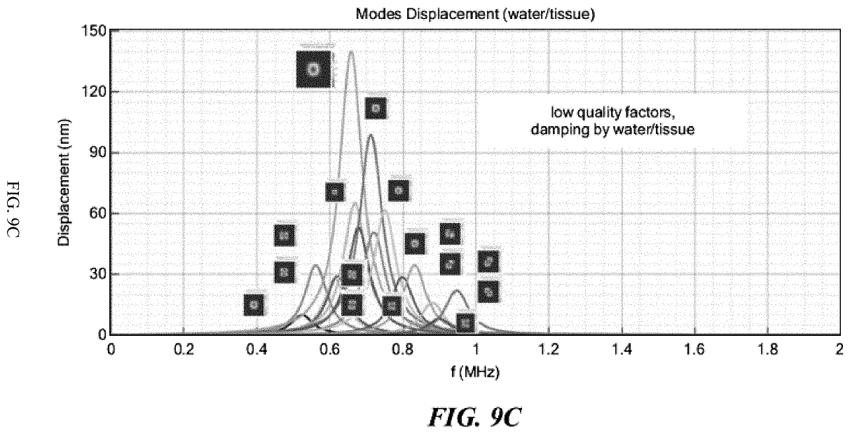

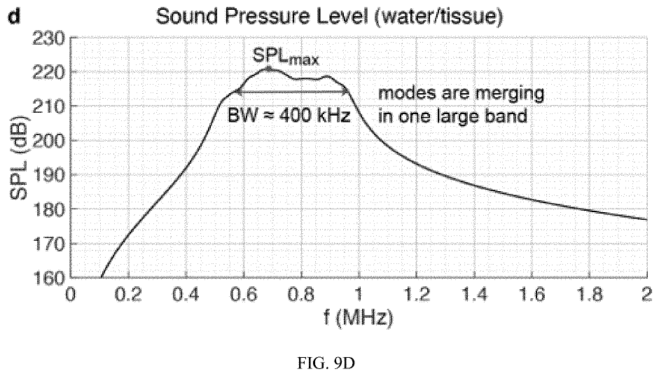

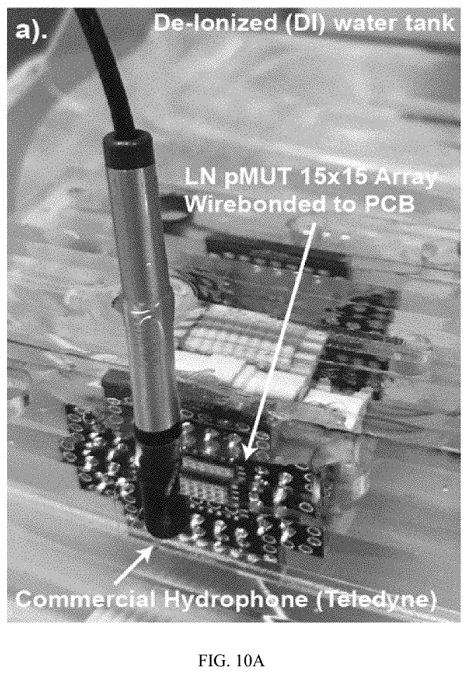

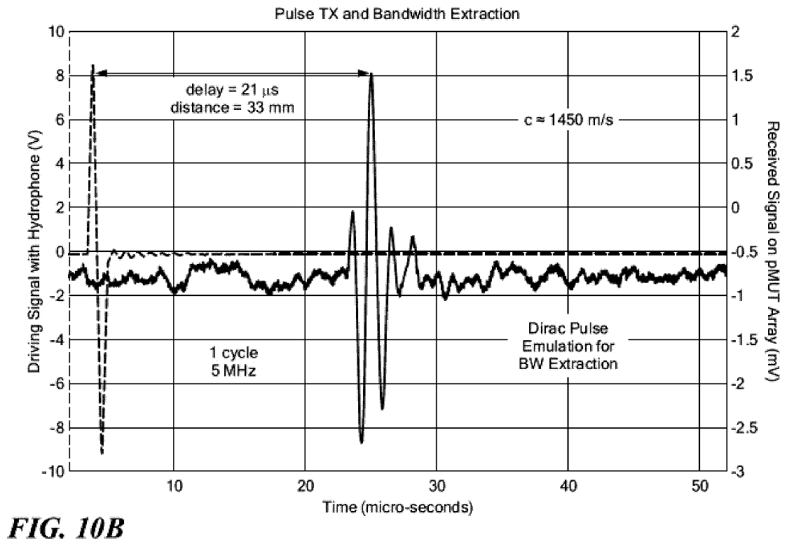

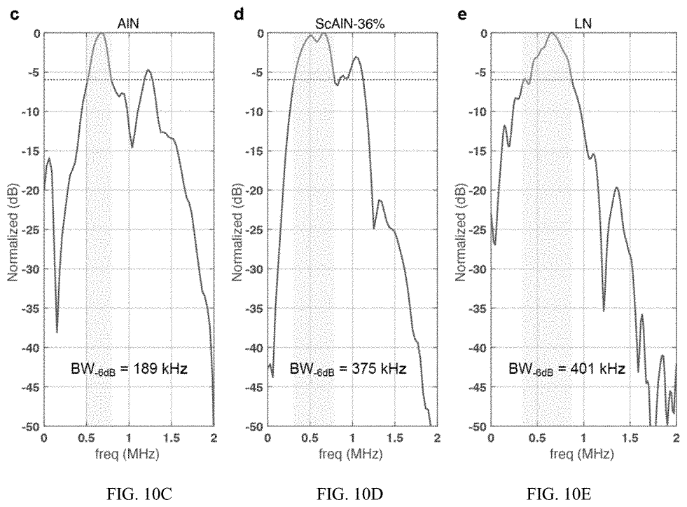

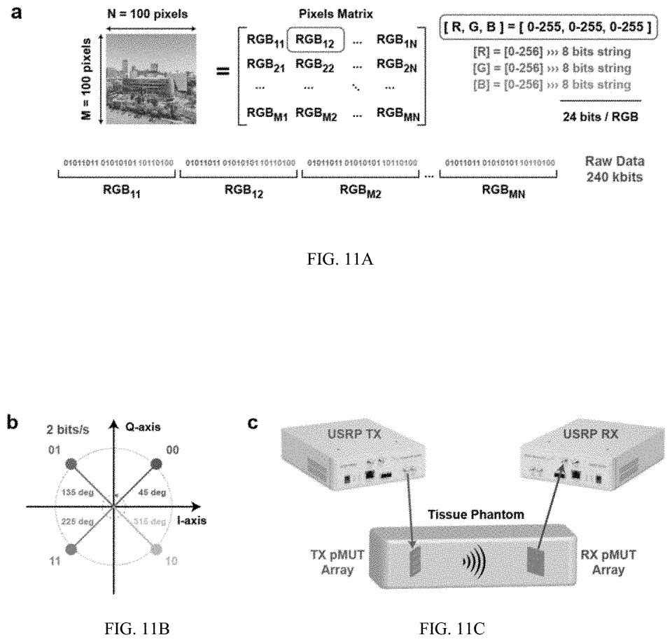

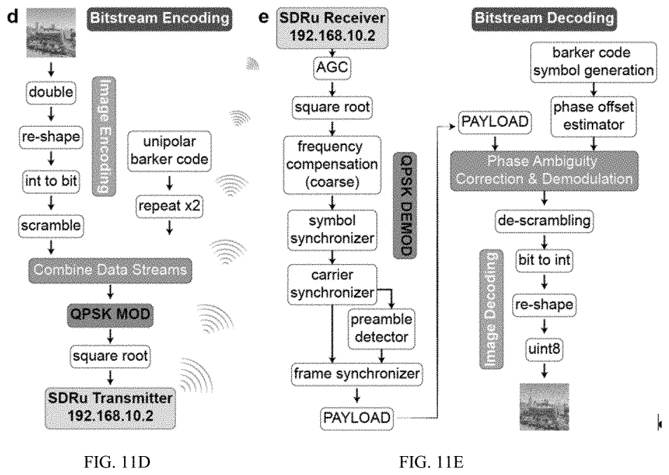

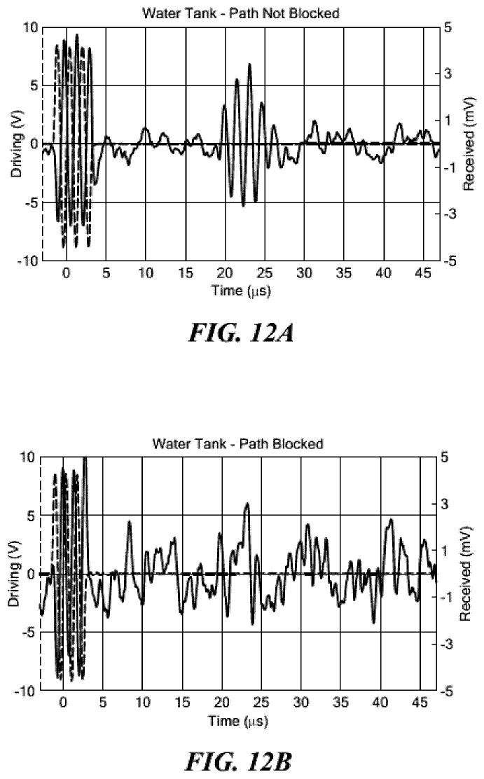

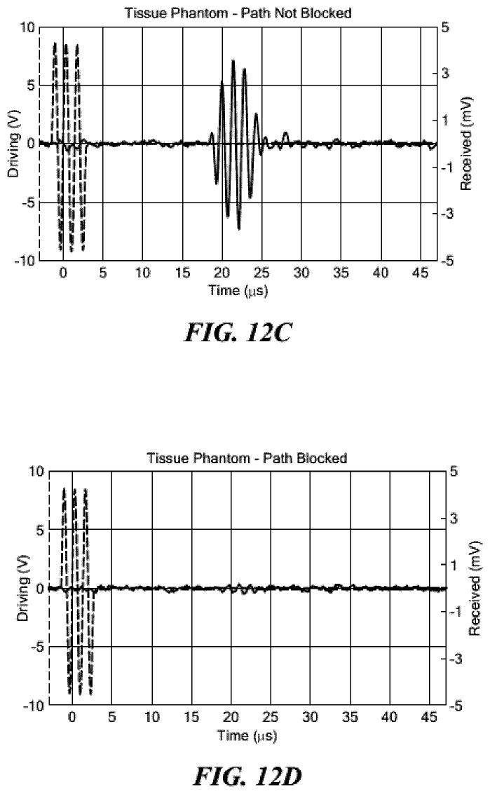

Multiphysics simulation based on their shape. It can be seen that the peaks are separated from each other due to a high-quality factor in air. The different colors represent different modes extracted from the measurement in air from FIG. 5A. FIG. 9B shows simulated combined Sound Pressure Level (SPL) of the device in air. It can be seen that the different peaks are not merging; instead multiple fractional bands have formed. FIG. 9C shows displacement modeling of the resonance peaks under the damping effect of the water and tissue medium. Here the quality factor is getting lower and closer to one another. The different colors represent different modes extracted from the measurement in air from FIG. 5A and then modeled under the damping effect of the water, by decreasing the quality factor. FIG. 9D shows modeling of the computed output SPL resulting in a unified large band of BW≈400 kHz, matching very closely with the reference hydrophone measurement.

FIGS. 10A-10E illustrate ultrasonic setup, bandwidth extraction and comparison. FIG. 10A shows a measurement setup for ultrasonic transmission between a commercial hydrophone (Teledyne) and the LN pMUT array submerged in a De-Ionized (DI) water tank. FIG. 10B shows Dirac pulse transmission to extract the pMUT bandwidth (BW) with a Fast Fourier Transform (FFT). The driving signal is shown in a dashed line, and the received signal is shown in a solid line. FIG. 10C shows bandwidth (BW) of an AlN pMUT. FIG. 10D shows bandwidth (BW) of a ScAlN-36% pMUT. FIG. 10E shows bandwidth of the LN pMUT in this work, at the same frequency of AlN and ScAlN based pMUTs for comparison.

FIGS. 11A-11E illustrate a data encoding and communication scheme. FIG. 11A shows image encoding. FIG. 11B shows a QPSK constellation. FIG. 11C shows a testing setup. A power amplifier was used to boost the output voltage of the TX USRP and a charge amplifier was used to detect the incoming signal at the RX USRP. Both TX and RX were pMUT arrays. FIG. 11D shows a 100×100 pixels image of the Northeastern University campus serialized into a bitstream in MATLAB. Further, this was encoded with a QPSK modulation and transmitted over an USRP in Simulink. FIG. 11E shows the transmitted data was received over the ultrasonic channel and synchronized with a second USRP in Simulink. Finally, the data was decoded from the QPSK modulation and re-shaped into a 2D RGB image.

FIGS. 12A-12D illustrate a time domain comparison of pulse transmission. The driving voltage is shown in a dashed line and the received voltage is shown in a solid line. FIG. 12A shows pulse transmission in water in which both ultrasonic pulse and capacitive coupling signals are present. FIG. 12B shows pulse transmission in water with path blocked, and in which only capacitive coupling is present. FIG. 12C shows pulse transmission in tissue phantom, in which only the ultrasonic pulse is present, and the capacitive signal disappeared. FIG. 12D shows pulse transmission in water with path blocked, and in which the ultrasonic pulse disappears as well.

### DETAILED DESCRIPTION

The present technology provides embodiments of micromachined ultrasonic transducers (pMUTs) having improved properties. In some embodiments, the technology can provide the coupling of several modes of vibration around the resonance frequency to obtain a large bandwidth. In some embodiments, a pMUT membrane displacement can be activated with a lateral electric field using only top electrodes, hence simplifying fabrication of the device.

In some embodiments, a pMUT utilizes lithium niobate (LN) as the piezoelectric material. In some embodiments, LN can be X-cut, Y-cut, or Z-cut. Thin-film X-cut lithium niobate can proivde high performance in terms of kₜ² and Q for laterally vibrating resonators for RF applications, but it has not been used in pMUTs up to now. The properties of X-cut LN allow harnessing of multiple and stronger piezoelectric coefficients of the thin film and permit the activation of one or more flexural modes of vibration with only top electrodes, thus reducing the fabrication cost, complexity, and reliability issues. In some embodiments, a LN pMUT includes an un-patterned suspended membrane activated only by top electrodes, where an AC voltage signal is applied, while a bottom electrode is left floating. This configuration generates an electric field in both the vertical and horizontal directions, thus harnessing multiple piezoelectric coefficients of the thin film LN.

The present technology can provide a number of advantages. For example, the technology can provide the ability to achieve larger bandwidth pMUTs compared to pMUT transducers based on other piezoelectric materials. The technology can achieve a higher electro-mechanical coupling factor (kₜ²) than other pMUTs, which allows for more efficient energy transformation from the electrical to the mechanical domain, and hence higher efficiency generation of ultrasonic radiation. The technology can enable high transmitting and receiving sensitivity due to a larger displacement of the membrane than in other pMUTs. The pMUT can be fabricated in arrays. In some embodiments, the pMUT can be micro-fabricated in 8-inch industrial foundries. Each wafer can contain hundreds to thousands of pMUT devices, reducing the cost of a single bare chip.

The technology described herein can address challenges for intrabody communication, namely, to increase the data rate. By way of further explanation, operating at ultrasonic (US) frequencies such as 1 MHz avoids signal attenuation, but in return, it limits the data rate. This is opposed to what can be achieved with radio frequency (RF) antennas operating at much higher frequency but having a dramatic increase of attenuation in tissue, as shown in FIG. 5C. In water, the electromagnetic (EM) waves attenuate with a rate of 0.2 dB/cm, while the US waves attenuate at a rate of 0.002 dB/cm; even though the US waves attenuate much less, it only introduces a difference of 3 dB at 15 cm. As shown herein, when considering a tissue phantom, the EM waves attenuate at a rate of 4 dB/cm while the US waves attenuate only at a rate of 0.7 dB/cm; this introduces a difference of 50 dB at 15 cm when operating in tissue phantom, which is closer to the human body in terms of attenuation and acoustic impedance, hence making the US waves a better fit for intrabody communication.

As noted above, the technology described herein provides, in some embodiments, LN pMUTs. By way of further explanation, to increase the data rate, devices can be designed with a large operation bandwidth. PMUTs based on AlN and SLAlN already present a wider bandwidth compared to bulk PZT transducers, cMUTs or even PZT-based pMUTs. The additional resonances provided by LN pMUTs described herein are due to the strong anisotropic properties of the piezoelectric coefficients of the LN, which assist in achieving a large operation bandwidth. This effect happens because the electric field generated by the top electrodes excites multiple modes through different piezoelectric coefficients, which are strong in multiple directions, as opposed to other materials that have strong coefficients only in one direction (i.e., AlN, SLAlN, and PZT). Further, when submerging the pMUTs in a damping media such an aqueous or oil medium or biological tissue, several adjacent resonance modes merge together, resulting in an overall increased large bandwidth for the LN pMUTs.

The technology herein provides a better alternative by designing arrays of pMUTs that include elements centered around different frequencies. These frequencies are closely spaced to cover a certain desired bandwidth. Once the pMUT array is implanted in biological tissue or submerged in a liquid medium, the different resonance frequencies merge together, due to the damping effect of the medium, and achieve a large bandwidth. However, this poses challenges at the fabrication level to precisely tune the resonance frequency of each individual pMUT. To ultimately increase the communication bandwidth, embodiments of the technology herein employ a different piezoelectric material that enables the harnessing of multiple resonance frequencies in one device which can merge into a larger bandwidth when operating in a medium such as biological tissue of a mammalian or non-mammalian body.

In some embodiments, the piezoelectric material is X-cut lithium niobate (LN). By harnessing stronger piezoelectric coefficients compared to AlN and ScAlN, the LN pMUTs can cover a broad range of implantation depths and result in higher data-rates for the communication schemes.

The LN pMUTs can harness, for the main resonance mode, a different piezoelectric coefficient compared to traditional pMUTs. The PZT, AlN, and ScAlN-based pMUTs employ a piezoelectric thin-film sandwiched between a top and a bottom electrode to activate the d₃₁ piezoelectric coefficient. The vertical electric field excites an in-plane displacement. Instead, the LN pMUT described herein employs a combination of piezoelectric coefficients, i.e., d₃₁ and d₁₁, that strongly couple the electric field to displacement. These coefficients can be activated by electrodes that lie on the same plane. Thus only a single metal layer is needed.

Also, additional resonances occur due to the strong anisotropic properties of the piezoelectric coefficient's matrix of the LN, which assists in achieving a large operation bandwidth. This effect happens because the electric field generated by the top electrodes excites multiple modes through different piezoelectric coefficients, which are strong in multiple directions, as opposed to other materials that have strong coefficients only in one direction (i.e., AlN, SLAlN, and PZT). Thus, when the pMUTs are implanted or submerged in a damping media such as biological tissue or a liquid medium, several adjacent resonance modes can merge together, resulting in an overall increased large bandwidth for the LN pMUTs.

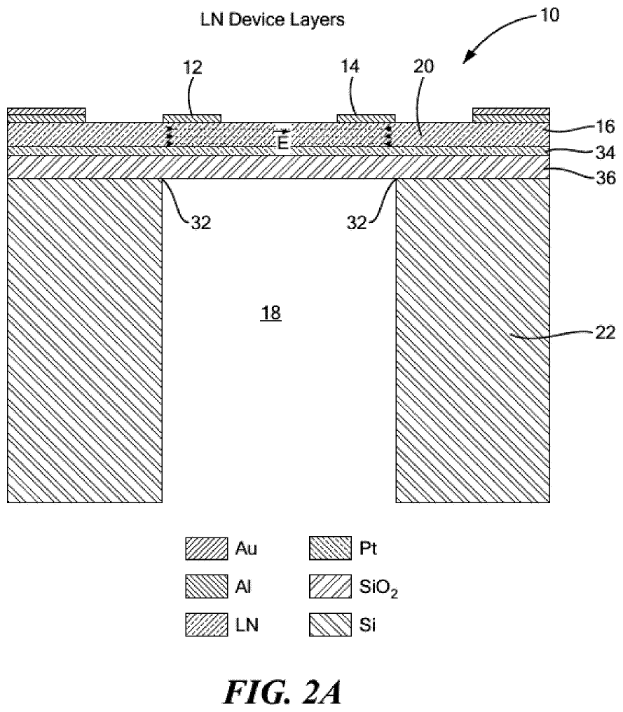

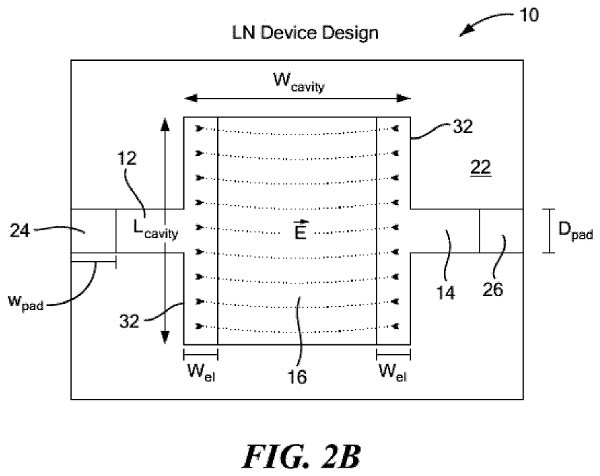

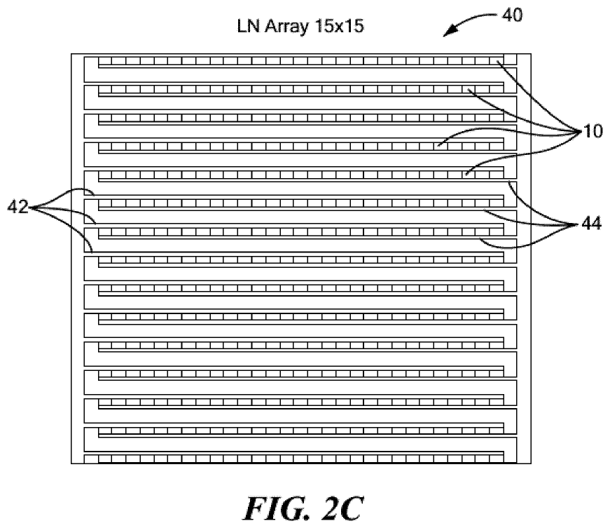

Referring to FIGS. 2A and 2B, an embodiment of a device 10 employing a single pMUT is shown. The device includes two activation electrodes 12, 14, e.g., signal and ground, supported on a piezoelectric layer 16 suspended over a cavity 18 to provide a vibrating membrane 20. More particularly, the device includes a substrate 22, an electrical input port 24 and an electrical output port 26 supported on the substrate, and a cavity 18 formed in the substrate. The membrane is suspended over the cavity and supported on the substrate along opposed edges 32 of the substrate 22 adjacent the cavity 18. The membrane comprises a piezoelectric layer having an upper surface facing away from the cavity.

The two activation electrodes are disposed on the upper surface of the membrane. The activation electrodes include an input or signal electrode in electrical communication with the electrical input port and an output or ground electrode in electrical communication with the electrical output or ground port. Each of the input electrode and the output electrode are disposed over the cavity in the substrate and in a parallel alignment with a corresponding one of the opposed edges of the substrate. In some embodiments, the input electrode and the output electrode can extend the full length of the cavity. Circuitry in communication with the activation electrodes can apply an input signal to excite one or more modes of mechanical vibration in the membrane, including a flexural mode of vibration having a displacement in a cross-sectional plane of the membrane.

In some embodiments, the membrane 20 can also include a bottom electrode 34 that can extend continuously over the cavity 18 to assist in defining the electrical field generated in the piezoelectric layer by the activation electrodes. The bottom electrode can be a floating electrode unconnected to the circuitry. In some embodiments, the membrane can include a support layer 36 to assist in supporting the piezoelectric layer and in handling the membrane during fabrication, described further below.

In some embodiments, the piezoelectric material can be lithium niobate (LN). In some embodiments, the LN can be X-cut lithium niobate, Y-cut lithium niobate, or Z-cut lithium niobate. In some embodiments, the material of the two activation electrodes can be aluminum. In some embodiments, the material of the two activation electrodes can be aluminum, titanium, or gold or combinations thereof. In some embodiments, the material of the two activation electrodes can be a dual layer of titanium and gold. In some embodiments, the material of the two activation electrodes can be a metal or combination of metals that can be micro fabricated, e.g., sputtered/evaporated and patterned with photolithographic techniques. In some embodiments, the material of the bottom electrode can be platinum. In some embodiments, the material of the bottom electrode can be platinum, aluminum, or molybdenum or combinations thereof. In some embodiments, the material of the support layer can be silicon dioxide or silicon nitride. In some embodiments, the material of the support layer can be silicon if silicon on insulator (SOI) wafers are used. In some embodiments, the material of the substrate can be silicon. In some embodiments, the material of the substrate can be silicon, quartz, or sapphire or combinations thereof.

In some embodiments, the device can have an operable bandwidth of a transmitted sound pressure level of at least 300 kHz, 350 kHz, 400 kHz, 450 kHz, 500 kHz, 1 MHz, 10 MHz, or 100 MHz. In some embodiments, the device can have an operable bandwidth of a transmitted sound pressure level of less than 300 kHz or greater than 100 MHz. In some embodiments, the device can have one or more peak resonance frequencies of an output signal in the range from 300 kHz to 1 MHz, or from 400 kHz to 800 kHz, or from 500 kHz to 700 kHz. In some embodiments, the device can have one or more peak resonance frequencies of an output signal less than 300 kHz or greater than 700 kHz.

In some embodiments, the cavity has a width dimension, w_{cav}, between the opposed edges of the substrate ranging from 1 μm to 1 mm, or from 30 μm to 500 μm. In some embodiments, each of the input electrode and the output electrode has a width dimension, Wₑ₁, ranging from 1 μm to 100 μm. In some embodiments, each of the input electrode and the output electrode has a thickness dimension ranging from 10 nm to 500 nm, or from 20 nm to 200 nm. In some embodiments, the piezoelectric layer has a thickness dimension ranging from 500 nm to 5 μm. In some embodiments, the bottom electrode has a thickness dimension ranging from 10 nm to 500 nm, or from 20 nm to 200 nm. In some embodiments, the support layer has a thickness dimension ranging from 500 nm to 5 μm. Dimensional tolerances can be ±0.5%, ±1%, ±2%, ±5%, ±10%, ±15%, or ±20%.

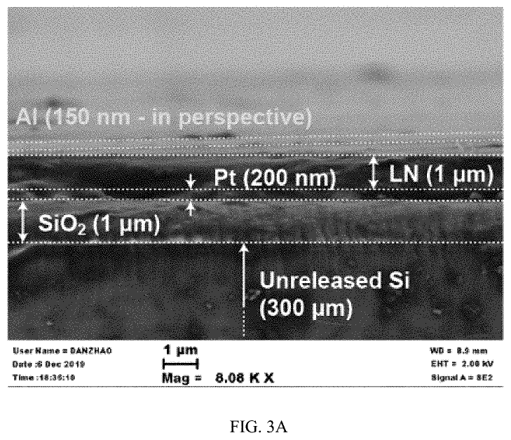

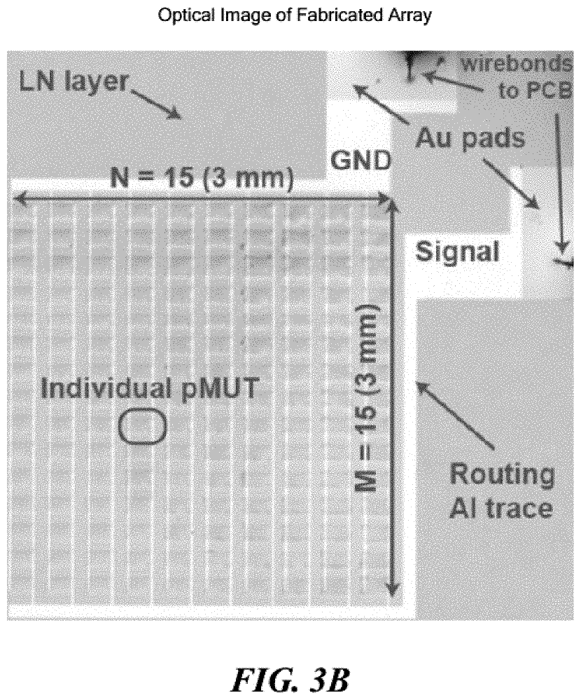

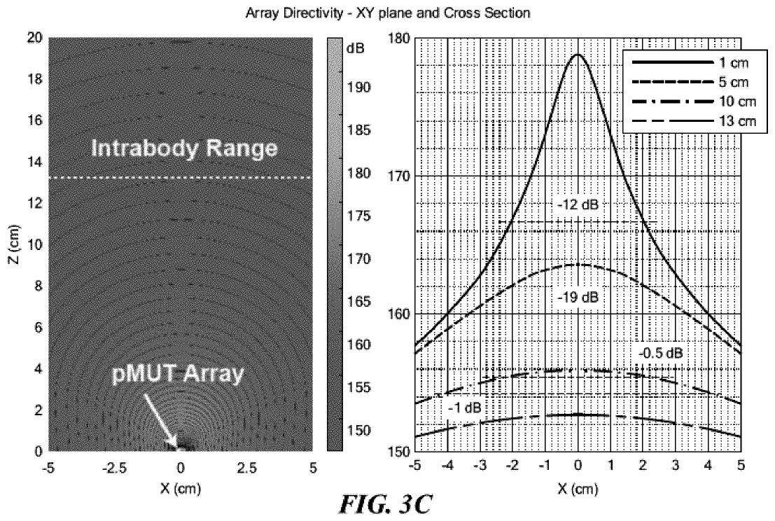

FIG. 3A is a scanning electron microscope (SEM) image of a fabricated LN pMUT, not yet released from the substrate. The image shows the various layers such as a Si substrate, SiO₂ support layer, a Pt bottom electrode layer (optional), a LN thin-film piezoelectric layer, and a top activation Al electrode (in perspective).

In a further embodiment, a US transducer can include two or more pMUTS. FIG. 2C shows an embodiment employing an array 40 of 15×15 pMUT devices 10. The input electrodes of each device can be electrically connected to each other in rows 42. Similarly, the output electrodes of each device can be electrically connected to each other in rows 44. The rows of the input electrodes can be interdigitated between the rows of the output electrodes. FIG. 3B shows an optical image of a fabricated 15×15 array of pMUT devices. The individual pMUTs and their released cavities (in a darker shade) can be distinguished. Routing traces connect the input ports and the output ports in parallel to combine the received and transmitted pressure. Pads of gold serve to wire-bond the array to a printed circuit board (PCB). This array can fit into a 3×3 mm² area, making it suitable to implant into a human body alongside IMDs.

In some embodiments, one or more pMUT devices can be implemented in an ultrasonic transducer device using a communication link. In some embodiments, the electronics can be implemented in CMOS circuitry or miniaturized field programmable gate arrays (FPGA). Any suitable communication protocol, such as a quadrature phase-shift keying (QPSK) modulation scheme, can be used.

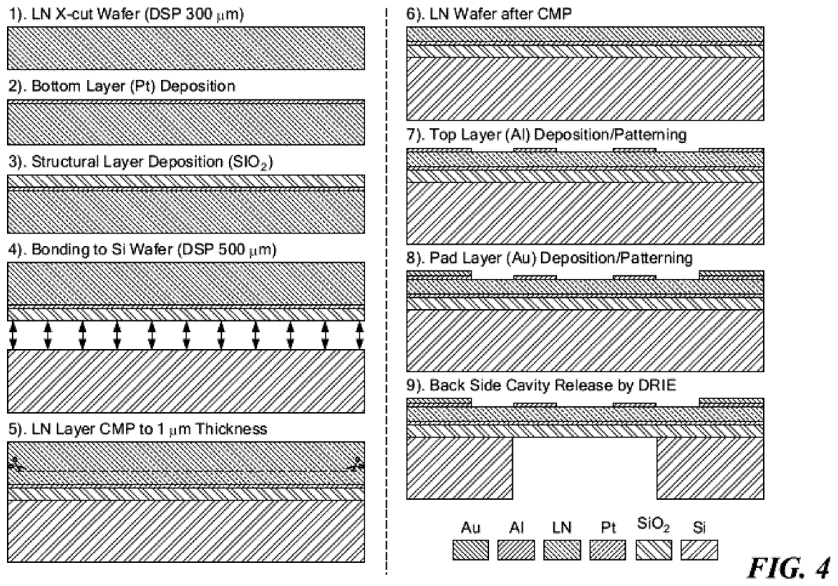

An embodiment of a fabrication process for a pMUT employing X-cut LN as the piezoelectric layer is described with reference to FIG. 4. The process starts with a thin film piezoelectric material. In some embodiments, an X-cut LN wafer of 300 μm can be used. A metal layer that can serve as a bottom electrode can be sputtered on one surface of the piezoelectric layer. In some embodiments, a Pt layer of 200 nm can be used. A support layer can be added, e.g., through chemical vapor deposition, to the bottom electrode layer. In some embodiments, the support layer can be a SiO₂ layer of 1 μm. The presence of this support layer shifts the neutral bending axis of the pMUT device to the middle of the piezoelectric layer, which can help to maximize the membrane displacement during activation. At this stage, the piezoelectric layer has been serving as a handling wafer for the bottom electrode and the support layer, rather than as a device layer.

Thus, the structure is transferred to another handling wafer. To achieve this transfer, the piezoelectric layer is flip bonded to a substrate, e.g., with a surface activated bonding technique. In some embodiments, the substrate can be a double side polished (DSP) Si wafer of 300 μm thickness. The piezoelectric layer is then reduced to a suitable device thickness, e.g., through a chemical and mechanical polishing (CMP) process. In some embodiments, the device thickness is 1 μm. Now, the piezoelectric layer is a device layer, and the substrate acts as a handling wafer. Next, patterning masks can be used to lithographically implement a desired design configuration of the one or more pMUTs, including both single-elements and array layouts. An electrode definition mask is used to define the top activation electrodes that can be, e.g., electron-beam sputtered and shaped through a lift-off process. Bonding pads, e.g., of gold, can be deposited at appropriate locations on the activation electrodes. A cavity releasing mask is used to define the pMUT cavities during a releasing process. This step can employ, e.g., a deep reactive ion etching (DRIE) process to etch straight trenches (i.e., cavities) from the back of the substrate layer and stop on the membrane support layer, thus releasing the pMUT membrane.

The present technology can be used in a variety of applications, such as intrabody communication with implanted medical devices; underwater communication; time-of-flight measurements; fingerprint sensors; power transfer applications; range finding applications; and social distancing sensors (e.g., to track COVID-19 or other infections). The technology can provide intrabody communication links that allow wireless communication between implanted and non-implanted devices.

### EXAMPLES

X-cut LN-based pMUTs were fabricated as described above and were implemented individually, in an array, and in a communication system. This allowed the creation of wide band and high data rate intrabody communication links with a high implantation depth range. FIGS. 2A and 2B show the design of a single LN pMUT. FIG. 2C shows the design of an array of pMUTs. FIG. 3A shows a scanning electron microscope (SEM) image of a fabricated device. FIG. 3B shows an optical image of a fabricated array.

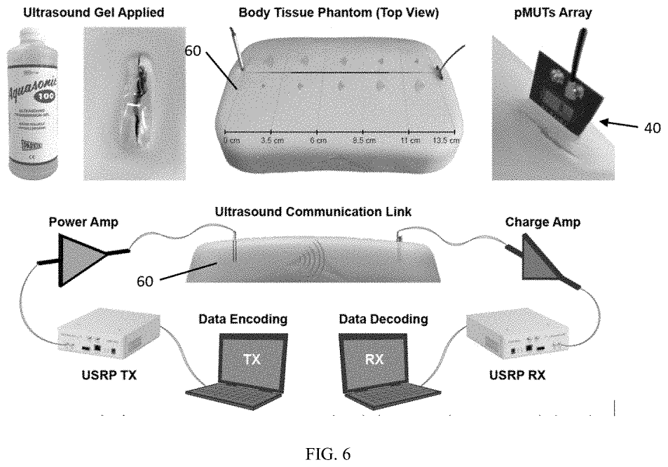

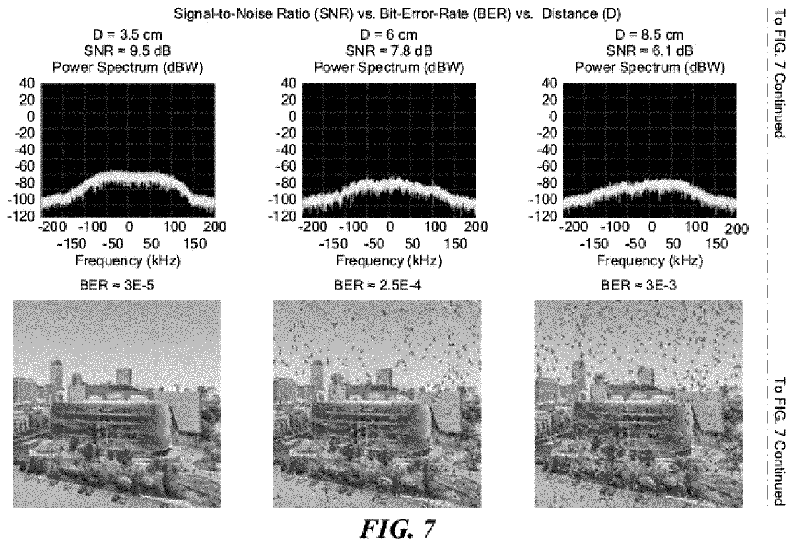

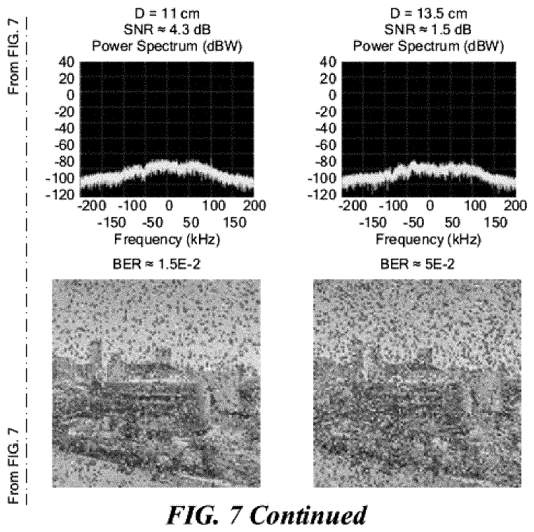

The properties of the LN pMUTs were characterized in air and in tissue-like media. The characterization in air consisted of measuring the 3D membrane displacement of the pMUT's membrane with a digital holographic microscope (DHM). The measurements matched the resonant modes predicted by a finite element simulation (FEM) as shown in FIG. 5A and described further below. These results showed that, with activation of only two top electrodes, multiple resonance modes could be excited around the main peak and that these were very distinctively separated for in-air operation. Following, the characterization in tissue-like media (de-ionized water, silicone oil, castor oil, or tissue phantom) consisted of transmitting a high intensity and short duration signal with a reference hydrophone and then receiving this ultrasonic signal at a certain distance with a LN pMUT array, described further below. This allowed the recovery of the intensity of the received signal and the determination of the bandwidth and maximum achievable distance. FIG. 5B shows the extracted bandwidth from the sound pressure level (SPL) received by the pMUT array. A communication setup through a body tissue phantom was implemented with the aid of two Universal Software Radio Peripheral (USRPs), as shown FIG. 6 and described further below. The communication results, representing the quality of the channel, are shown in FIG. 7 for different communication distances or depths.

pMUT Membrane

The displacement of the pMUT membrane was measured over the frequency range with a digital holographic microscope (DHM) as shown in FIG. 5A. The DHM created a full 3D reconstruction of the membrane which allowed for a precise measurement, both in terms of peak displacement and vibration mode. The figure shows the maximum membrane displacement of several pMUT samples and their mean value profile curve (“black-bold” curve). At this point, from the same curve, the main resonance frequency was determined to be around fᵣₑₛ=660 kHz and the maximum displacement to be dₘₐₓ=240 nm when applying an input voltage of Vᵢₙ=3 V, resulting in a displacement sensitivity of S_{disp}=80 nm/V. Moreover, each major resonance peak was matched with a finite element analysis (FEA) simulation in COMSOL Multiphysics. As discussed above, the additional resonances are due to the strong anisotropic properties of the piezoelectric coefficients of the LN, which assist in achieving a large operation bandwidth. This effect happens because the electric field generated by the top electrodes excites multiple modes through different piezoelectric coefficients, which are strong in multiple directions, as opposed to other materials that have strong coefficients only in one direction (i.e., AlN, ScAlN, and PZT). At this point, when submerging the pMUTs in a damping media such a tissue phantom or silicon oil, several adjacent resonance modes can merge together, resulting in an overall increased large bandwidth for the LN pMUTs.

A time-domain measurement of the membrane displacement was performed with a laser doppler vibrometer (LDV). The resonance frequency obtained from the LDV was fᵣₑₛ≈699 kHz and the peak displacement was dₘₐₓ≈88 nm for an input signal of Vᵢₙ=1 V, resulting in a displacement sensitivity S_{disp}≈88 nm/V (confirming the 3D DHM measurement). While, on one hand, this technique allowed the measurement of the displacement in only one point in the pMUT membrane, it also allowed for a time-domain characterization. The time-domain approach allowed the pMUT membrane to be driven with several sine wave cycles (N=800) and measuring of the ring-up and the ring-down of the membrane displacement, which is a function of the resonance quality factor, which resulted to be Q≈381.

pMUT Array

A 15×15 LN pMUT array was fabricated as described above and as shown in FIGS. 2C and 3B. The array was wire-bonded to a printed circuit board (PCB) and covered in a thin Parylene layer. This layer had two functions, to protect the wire-bonds and to act as a matching layer between the pMUT acoustic impedance and the operating medium impedance. The LN array was submerged in a de-ionized (DI) water tank, to closely match the acoustic impedance of human tissue, and tested for its ultrasound transmission capabilities. The Fast Fourier Transform (FFT) was applied to the received pulse on this measurement, to extract the frequency domain response shown in FIG. 5B. From the graph, the operation bandwidth of the pMUT was extracted at −6 dB, which corresponded to a large bandwidth BW_{-6 dB}≈401 kHz at a center frequency of f_{c}≈630 kHz. It can be noted that the resonance frequency was lowered in the DI water due to the damping effect and at the same time the modes shown in FIG. 5A were merged inside one large band. Similarly, the quality factor in water was determined to be Q≈2, which was two orders of magnitude lower than in air, indicating a good ultrasound radiation in water or tissue-like media.

### Communication Link

Once the LN pMUT arrays were characterized for ultrasound transmission, a communication link was set up to emulate as closely as possible an intrabody communication scenario, as shown in FIG. 6. The intrabody setup included a body tissue phantom 60 from 3B Scientific that mimiced the human body properties, such as propagation speed of the ultrasound waves, an average body density, and its corresponding acoustic impedance. An incision was performed on the phantom to implant the pMUT array receiver. To avoid air gaps around the implanted array, an ultrasound gel similar to one used for ultrasound imaging was applied, which gave continuity to the ultrasound transmission. The communication link was implemented with Universal Software Radio Peripherals (USRP). This allowed the implementation of a communication scheme of choice in MATLAB Simulink and testing in real-time in the intrabody scenario.

The implementation demonstrated the high performance of the LN pMUT arrays, in an intrabody scenario, in terms of large bandwidth and long intrabody communication range. To take full advantage of the large 400 kHz bandwidth provided by the LN pMUTs, a quadrature phase-shift keying (QPSK) modulation scheme was used as the communication protocol. Row pixels of an image were transmitted over the ultrasound link and then the information was serialized into a bitstream. The encoding and the QPSK modulation are described further below. The bitstream was fed directly into a QPSK modulator object provided in MATLAB Simulink which interfaced with the USRP Software Defined Radio (SDR) transmitter. The SDR transmitter was in charge of up converting the modulated data from baseband (DC center frequency) up to the RF frequency corresponding to the central frequency of the pMUT array transmitter f_{c}≈630 kHz. After transmission, the received data was decoded with a decoding MATLAB script (the reverse procedure used to encode) and reassembled into an image. The received image was compared with the originally transmitted one in terms of bit error rate (BER) at several communication distances or implanted device penetration depths. The BER degraded with lower SNR at longer distance. By choosing an image as transmitted data, the quality of the ultrasonic channel could be visually interpreted in terms of lost pixels (“black”) or degraded pixels (“un-real colors”).

Once the communication setup was ready to transmit and receive, testing was performed. The main test consisted of characterizing the quality of the ultrasonic channel in the tissue phantom at different distances, starting from a minimum of Dₘᵢₙ=3.5 cm and a maximum distance in the phantom of Dₘₐₓ=13.5 cm. The results are shown in FIG. 7. The signal-to-noise ratio (SNR) obtained for such communication depth range had a maximum of SNRₘₐₓ=9.5 dB and reached a minimum of SNRₘᵢₙ=1.5 dB, as shown in the power spectrum of the QPSK modulation. Under these SNR conditions, the amount of pixel errors was computed when receiving the encoded image, a metric known as BER. To have a direct interpretation of the BER and thus of the quality of the ultrasonic channel based on the LN pMUT arrays, FIG. 7 shows the de-coded image for each distance. These images show how some pixels got “lost” or had the wrong information resulting in abrupt color changes compared to other adjacent pixels. On one hand, the BER had a minimum of BERₘᵢₙ=3×10⁻⁵ when real-time data transmission was directly implemented on the communication channel without additional coding or electronics. On the other hand, the BER had a maximum of BERₘₐₓ=5×10⁻², which is the limit for being able to correctly reconstruct the original information by implementing bit error detection and correction algorithms. The BERₘₐₓ set the limit to the implantation depth of the IMD to maintain reliable ultrasonic data transmission. Additionally, the experimental BER vs. SNR was plotted in the initial theoretical curve for a QPSK link in FIG. 5D, showing the logarithmic decrease of the communication errors while the signal level decreased at longer implantation depths.

These results support a broad implantation range D_{range}=3.5-13.5 cm, which can enable the implantation in a variety of IMDs and at the same time offer a large communication bandwidth of BW=400 kHz. Ultimately, this visual interpretation of the ultrasonic channel quality can be useful for applications such as scanning for multiple IMDs to find an optimal location for the external transmitter.

In conclusion, given the results in terms of large bandwidth and deep implantation range, the LN-based pMUT technology described herein can improve the wireless communication links for implanted medical devices for real-time monitoring. The LN piezoelectric thin film shows promising insights on how to achieve a large band thanks to the combination of spurious modes under the damping of the acoustic medium such as water and tissue.

### COMSOL Simulation and Air Measurements of Fabricated Devices

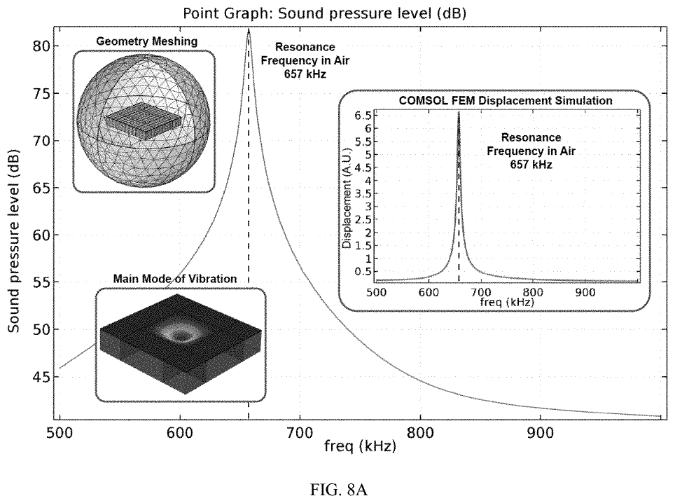

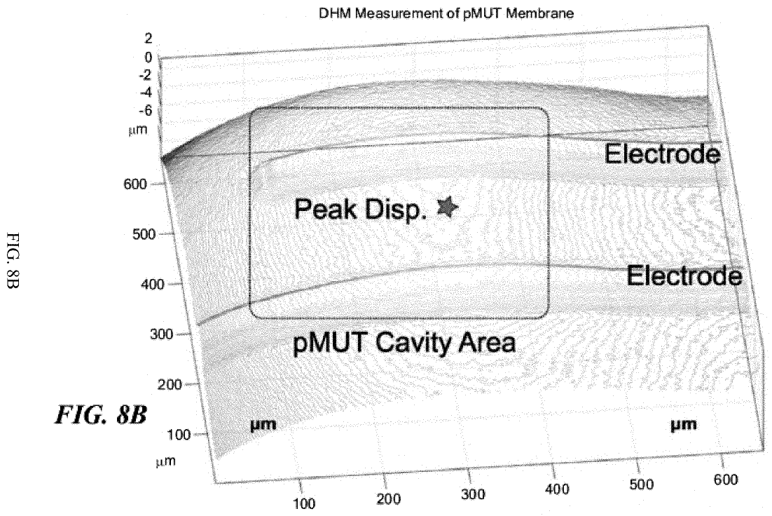

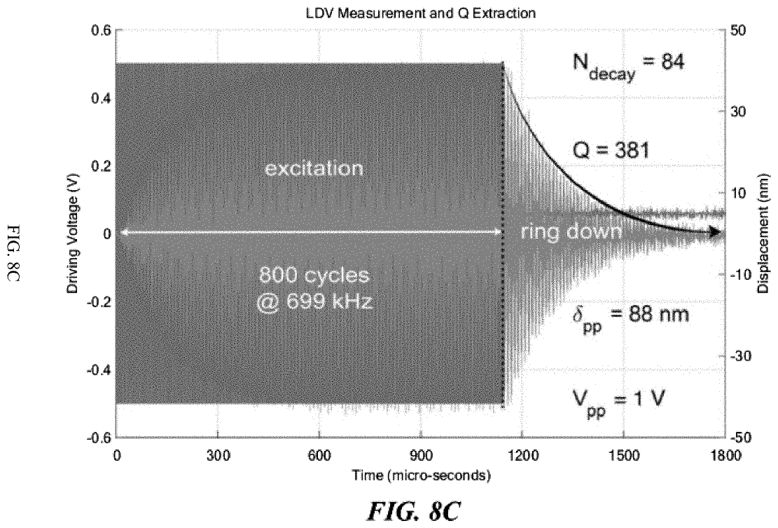

To simulate the pMUTs, COMSOL Multiphysics was used to generate a 3D model of a single LN pMUT and to run a finite element analysis (FEA) to find its behavior in the frequency domain. Besides providing several physics domains for the models, the advantage of using COMSOL was that it also provided coupling modules between these different domains. To simulate a pMUT element, two multi-physics modules were used: a piezoelectric module, which coupled the electrical domain with the mechanical one, and an ultrasonic module, which coupled the mechanical domain with the sound-pressure domain in different materials. This simulation tool allowed the setup of an application medium such as air and tissue-like media (oil, water, tissue-phantom) and the selection of a particular thin film layer as the piezoelectric layer. This allowed selection of a LN cut (i.e., crystal orientation and piezoelectric coefficient matrix), in this case the X-cut, and the angle of orientation at which the electric field is applied. In FIG. 8A, the sound pressure level (SPL) generated by the pMUT is shown while sweeping the operation frequency. Here a resonance frequency of 657 kHz was detected in air where the SPL was maximum. The three inserts show the geometry meshing, the main mode of vibration, and the membrane displacement over frequency.

Once the devices were fabricated, they were characterized in air with a digital holographic microscope (DHM) to measure the full 3D displacement of the pMUT's membrane, as shown in the reconstruction in FIG. 8B, and to detect the mode shape. Here a main resonance of fₐᵢᵣ≈669 kHz (a close match to the simulation) and an average peak displacement sensitivity of S_{disp}≈93 nm/V were measured. Also, the peak displacement was measured with a laser doppler vibrometer (LDV) while driving the pMUT with N=800 sine wave cycles at the resonance frequency in air. This allowed extraction of its quality factor Q with the ring-down technique. This consisted of counting how many cycles it took to halve the displacement amplitude once the driving signal was turned off, and then multiplying this number by 4.53 to find the quality factor Q. In this case the ring-down decay took N_{decay}=84, as shown in FIG. 8C, thus Qₐᵢᵣ≈381. In another case, ring-down decay took N_{decay}=80, with Vₚₚ=5 V, Q=362, δₚₚ=472 nm.

### Modes Merging in Air vs Water/Tissue

The LN pMUTs present interesting piezoelectric properties for which multiple resonance modes can be activated around the main resonance frequency. With a frequency sweep on the DHM, the additional resonance modes can be detected based on the shape of the 3D displacement of the membrane as shown in FIG. 8B. The modes were extracted from the measurement and fitted to a Butterworth Van-Dike (BVD) model based on their frequency, quality factor, coupling factor, and peak displacement, as shown in FIG. 9A. Since these measurements were performed in air the quality factor of each resonance was high, making them very distinctive from one another. This was due to the high acoustic impedance mismatch to the air which prevented the ultrasonic radiation and kept most of the energy on displacing the pMUT's membrane. Similarly, the air has a low density; thus the damping of the displacement was low as well. FIG. 9B shows the simulated combined SPL at the output of the LN pMUT surface based on the above measurements. As can be noticed, the peaks did not merge together but rather formed multiple fractional bands, because of the high-quality factor of each peak in air.

What happened to the peak displacements of all the resonance modes and to the combined output SPL of the LN pMUT when exposed to a denser external load, such as water or a tissue phantom, were modeled. First, in FIG. 9C the displacement attenuation of each resonance peak and the lowering of their corresponding quality factor can be noticed. This was due to the more efficient radiation of the energy from the pMUT surface into the medium by generating ultrasonic waves. Moreover, given the high density of the new medium, this also had a damping effect on the displacement amplitude of each resonance peak, allowing them to merge into a single output pressure band as shown in FIG. 9D. In this case the resulting large bandwidth of BW_{-6 db}≈400 kHz was a very close match to the measured results in FIG. 5B with a reference hydrophone at a radiation distance of 3.3 cm.

### Ultrasonic Measurement Setup, Bandwidth Extraction and Comparison

The 15×15 LN pMUT array was coated with polydimethylsiloxane (PDMS) and submerged in a de-ionized water tank and tested for ultrasonic transmission as shown in FIG. 10A. This showed a record bandwidth of BW_{-6 dB}≈401 kHz and a center frequency f_{water}≈630 kHz. In addition, Q_{water}≈2 was lower than in Qₐᵢᵣ, implying that most of the input energy was radiated into the medium, making the LN pMUT suitable for underwater and intrabody communication. FIG. 10B shows the driving signal (dashed curve) of a hydrophone and the received pulse by a LN pMUT array (solid curve). The hydrophone was excited with a high intensity pulse to emulate a Dirac pulse, V_{Dirac}=9 V and f_{Dirac}=5 MHz, which allowed extraction of the step response of the system. It is interesting to notice that the received signal was delayed by 21 μs at a distance of 3.3 cm, allowing the estimation of the sound velocity in the water to be c≈1450 m/s. Finally, the received pulse had an intensity of V_{RX}≈4.2 mV.

The fabricated LN pMUTs were compared to devices based on other materials, such as AlN as shown in FIG. 10C and SLAlN doped at 36% as shown in FIG. 10D, and then compared to the bandwidth obtain for LN pMUTs as shown in FIG. 10E. The impulse response was measured in a water tank as in FIG. 9B and FFT was applied for bandwidth extraction at −6 dB from the peak as shown in FIG. 5B. The LN-based pMUTs showed the highest bandwidth of 401 kHz, while the 36% Sc-doped AlN showed large bandwidth of 375 kHz as well, which makes it a good material. However, a disadvantage of the Sc is the reproductivity of the sputtering process, while the advantage of the LN is that during the bonding process to the substrate it maintains the same crystal structure and piezoelectric properties, hence making it more reliable and predictable.

Data Serialization into a Bitstream and Modulation Scheme Implementation

A raw image of 100×100 pixels was serialized in MATLAB to create a bit stream for the communication scheme as shown in FIG. 11A. Each pixel consisted of an RGB vector of 3 integers (0-255) that can be converted into an 8-bit string, for a total of 24 bits for the vector. All the pixels were concatenated in a bit stream resulting in a total raw data of Data_{RAW}=240 kbits. Then, the bit stream was encoded with a Quadrature Phase Shift Keying (QPSK) modulation, which allowed to encode 2 bits per second as shown in FIG. 11B. The modulation was done asynchronously eliminating the need for a clock. On the other hand, there was the need to add an overhead to the raw data in order for the receiver to detect it. This increase in data length was of approximately 10%, resulting a final Data_{QPSK}≈264 kbits. Finally, the QPSK data was up converted by the USRP at the operation frequency of the pMUT array and transmitted through a tissue phantom that mimics the human tissue properties, as shown in FIG. 11C. The pMUT array bandwidth equaled to BW≈400 kHz, translating in a DataRate≈800 kbits/s, meaning that the time to transmit one image or frame was T_{TX}≈0.33 seconds. On the receiving side of the intrabody ultrasonic transmission link, the signal was down converted to baseband by another USRP and sampled at twice the bandwidth for perfect reconstruction (Nyquist theorem). The signal required constant frequency and frame synchronization. The data bitstream was demodulated from the QPSK scheme and re-assembled in an RGB pixels matrix.

The generated bitstream was fed directly into a QPSK modulator object provided in MATLAB Simulink which interfaced with the USRP Software Defined Radio (SDR) transmitter. The SDR transmitter was in charge of up converting the modulated data from baseband (DC center frequency) up to the RF frequency corresponding to the central frequency of the pMUT array transmitter f_{c}=630 kHz, as shown in FIG. 11D. The encoded bitstream was received by a pMUT array receiver with the same central frequency, as shown in FIG. 11E. Since the receiver and the transmitter did not share a common clock, the major issue was synchronizing the SDRs at the two ends of the communication link. For this reason, three standard synchronization blocks were used for the QPSK modulation, such as frequency offset compensation, symbol, and carrier synchronization. This allowed maintenance of a stable ultrasound link and even stream of the data in real-time.

### Time Domain Comparison to Avoid Capacitive Coupling

When in water, the driving signal coupled directly into the received signal through a capacitive coupling effect, while the received ultrasonic pulse was received with a delay of 20 which indicated a distance of around 3 cm as shown in FIG. 12A. Then the ultrasonic path was blocked, and the capacitive coupling was still present in water, as shown in FIG. 12B. When repeating the same experiments in a tissue phantom, the capacitive coupling was not present anymore, as shown in FIG. 12C. In this plot it can be seen that the ultrasonic pulse was delayed by 20 μs at around 3 cm without any of the driving signal leaking into the received signal. Additionally, in FIG. 12D, the direct path was blocked again in between the TX and RX and the ultrasonic pulse was not present anymore. This shows that by using a tissue phantom in the experimental setup, capacitive coupling can be avoided in the ultrasonic pulse and hence a reliable communication link can be implemented.

As used herein, “consisting essentially of” allows the inclusion of materials or steps that do not materially affect the basic and novel characteristics of the claim. Any recitation herein of the term “comprising,” particularly in a description of components of a composition or in a description of elements of a device, can be exchanged with “consisting essentially of” or “consisting of.”

To the extent that the appended claims have been drafted without multiple dependencies, this has been done only to accommodate formal requirements in jurisdictions that do not allow such multiple dependencies. It should be noted that all possible combinations of features that would be implied by rendering the claims multiply dependent are explicitly envisaged and should be considered part of the invention.

What is claimed is:

1. A device for ultrasonic transmission and/or reception, the device comprising:
a substrate, an electrical input port and an electrical output port supported on the substrate, a cavity formed in the substrate;
a membrane suspended over the cavity, the membrane supported on the substrate along opposed edges of the substrate adjacent the cavity, the membrane comprising a piezoelectric layer having an upper surface facing away from the cavity;
two activation electrodes disposed on the upper surface of the membrane, the activation electrodes comprising an input electrode in electrical communication with the electrical input port and an output electrode in electrical communication with the electrical output port, each of the input electrode and the output electrode disposed over the cavity in the substrate and in a parallel alignment with a corresponding one of the opposed edges of the substrate; and
circuitry in communication with the activation electrodes to apply an input signal to excite a flexural mode of mechanical vibration in the membrane, the flexural mode of vibration including a displacement in a cross-sectional plane of the membrane.

2. The device of claim 1, wherein the piezoelectric layer comprises a material having two or more piezoelectric coefficients excitable by activation from the two activation electrodes to couple an electric field in the membrane to the displacement of the membrane.

3. The device of claim 2, wherein the two or more piezoelectric coefficients include a d₃₁ coefficient and a d₁₁ coefficient.

4. The device of claim 1, wherein the piezoelectric layer comprises lithium niobate (LiNbO₃).

5. The device of claim 4, wherein the lithium niobate is X-cut lithium niobate.

6. The device of claim 4, wherein the lithium niobate is X-cut lithium niobate, Y-cut lithium niobate, or Z-cut lithium niobate.

7. The device of claim 1, wherein the two activation electrodes are operable to activate two or more modes of displacement of the membrane.

8. The device of claim 1, further comprising a bottom electrode disposed on a lower surface of the piezoelectric layer facing toward the cavity, the bottom electrode unconnected to the circuitry.

9. The device of claim 1, wherein the membrane further comprises a support layer disposed on a lower surface of the piezoelectric layer facing toward the cavity, the support layer comprising a dielectric material, a non-conductive material, or an insulating material.

10. The device of claim 1, having an operable bandwidth of a transmitted sound pressure level of at least 300 kHz.

11. The device of claim 1, having one or more peak resonance frequencies of an output signal in the range from 300 kHz to 1 MHz.

12. The device of claim 1 configured for use in a liquid medium or in biological tissue.

13. The device of claim 1 configured for use underwater or implanted in a human or non-human mammalian body.

14. A plurality of devices of claim 1, wherein the plurality of devices are arranged in an array.

15. An ultrasonic transducer comprising one or more devices of claim 1.

16. The ultrasonic transducer of claim 15, further comprising communication circuitry including a data encoding modulation scheme for transmitting signals to the one or more devices or a decoding modulation scheme for receiving signals from the one or more devices or both.

17. A method of operating the device of claim 1, comprising applying an alternating voltage to the two activation electrodes to excite the flexural mode of mechanical vibration in the membrane.

18. The method of claim 17, further comprising:
placing the device in a liquid medium or biological tissue; and
transmitting an ultrasonic signal into the medium or tissue from the mechanical vibration of the device.

19. The method of claim 18, further comprising exciting two or more modes of displacement in the membrane, and the liquid medium or biological tissue comprises a damping medium, whereby several resonance frequencies merge together to increase a bandwidth of a transmitted ultrasonic signal into the liquid medium or the biological tissue.

20. A method of fabricating an ultrasonic transducer comprising:
depositing a support layer on a surface of a piezoelectric layer to form a membrane;
bonding the support layer of the membrane to a substrate;
depositing two activation electrodes to a surface of the membrane opposite the support layer, the two activation electrodes comprising an input electrode and an output electrode; and
forming a cavity in the substrate with the membrane suspended over the cavity and supported along opposed edges of the substrate adjacent the cavity, the support layer facing toward the cavity, and each of the input electrode and output electrode disposed over the cavity and in a parallel alignment with a corresponding one of the opposed edges of the substrate.
